(19) United States
(12) Patent Application Publication
(10) Pub. No.: US 2011/0235960 A1
(43) Pub. Date: Sep. 29, 2011

(54) OPTICAL MODULATOR AND MANUFACTURING METHOD THEREFOR

(75) Inventor: Takeshi Yamatoya, Tokyo (JP)

(73) Assignee: MITSUBISHI ELECTRIC CORPORATION, Tokyo (JP)

(21) Appl. No.: 12/945,965

(22) Filed: Nov. 15, 2010

(30) Foreign Application Priority Data
Mar. 26, 2010 (JP) 2010-073125

(51) Int. Cl. G02F 1/035; H01L 31/18

(52) U.S. Cl. 385/2; 438/69; 257/E31.127

(57) ABSTRACT

An optical modulator includes a modulation region for modulating light, and a passive region adjacent the modulation region. The modulation region and the passive region include, in common, a semiconductor substrate, an n-type cladding layer on the semiconductor substrate, a core layer on the n-type cladding layer, and a p-type cladding layer on the core layer. The modulation region further includes a contact layer on the p-type cladding layer, and a P-side electrode on the contact layer. The passive region further includes an undoped cladding layer between the core layer and the p-type cladding layer.

### BACKGROUND OF THE INVENTION

1. Field of the Invention

The present invention relates to an optical modulator including a modulation region and passive regions adjacent the modulation region, and to a method of manufacturing such an optical modulator.

2. Background Art

The semiconductor Mach-Zehnder modulator, which is a type of optical modulator, will be described. Semiconductor Mach-Zehnder modulators typically have a p-i-n layer structure. A p-i-n structure is a structure that includes an n-type cladding layer, an undoped core layer, and a p-type cladding layer stacked in that order on a semiconductor substrate of InP, etc.

p-i-n structures exhibit optical loss due to intervalence band absorption in the p-type cladding layer. Methods for reducing the optical loss include increasing the thickness of the core layer and forming an undoped cladding layer between the core layer and the p-type cladding layer. For example, Japanese Laid-Open Patent Publication No. H07-191290 discloses a structure in which an undoped cladding layer (i-InP cladding layer) having a thickness of 100 nm is interposed between the core layer and the p-type cladding layer. That is, the optical loss in the p-type cladding layer can be reduced by increasing the total thickness of the undoped layer or layers in the p-i-n structure. (It will be noted that the letter i in the notation p-i-n indicates the undoped layer or layers.)

Further, optical modulators having an n-i-n layer structure have been proposed to reduce the optical loss. This structure does not include a p-type cladding layer, which layer introduces optical loss, as described above.

There is a need to reduce the drive voltage of optical modulators, in addition to the need to reduce their optical loss. More specifically, it is desirable that optical modulators can be driven by a low voltage in order to accommodate the limited output amplitude of the drive ICs (or drivers) and to reduce the power consumption.

However, optical modulators having a p-i-n structure are difficult to design so that they can be driven by a low voltage if the undoped layer (including the core layer) in the structure has an increased thickness. Specifically, an increase in the thickness of the undoped layer of an optical modulator results in a reduction in the field strength in the layer, thereby reducing the amount of change in the refractive index of the core layer due to the quantum confined Stark effect (QCSE). In this case, it is necessary to increase the drive voltage of the optical modulator to produce the desired change in the refractive index of the core layer for optical modulation. That is, it has not been heretofore possible to reduce the optical loss in an optical modulator having a p-i-n structure while reducing its drive voltage.

Further, optical modulators having an n-i-n structure also have a disadvantage, since many semiconductor lasers have a p-i-n structure. Specifically, a complicated manufacturing method must be used to monolithically integrate an optical modulator having an n-i-n structure with a semiconductor laser having a p-i-n structure. Therefore, it has been found difficult to monolithically integrate an optical modulator having an n-i-n structure with a semiconductor laser having a p-i-n structure.

### SUMMARY OF THE INVENTION

The present invention has been made to solve the above problems. It is, therefore, an object of the present invention to provide an improved optical modulator operable with a decreased drive voltage which exhibits a decreased optical loss and which can be easily monolithically integrated with a semiconductor laser. Another object of the present invention is to provide a method of manufacturing such an optical modulator.

According to one aspect of the present invention, an optical modulator includes a modulation region for modulating light, and a passive region adjacent the modulation region. The modulation region and the passive region include, in common, a semiconductor substrate, an n-type cladding layer on the semiconductor substrate, a core layer on the n-type cladding layer, and a p-type cladding layer on the core layer. The modulation region further includes a contact layer on the p-type cladding layer, and a P-side electrode on the contact layer. The passive region further includes an undoped cladding layer between the core layer and the p-type cladding layer.

According to another aspect of the present invention, a method of manufacturing an optical modulator including a modulation region for modulating light and a passive region adjacent the modulation region, the method includes the steps of forming an n-type cladding layer, a core layer, a lower undoped cladding layer, an etch stop layer, and an upper undoped cladding layer in that order on a semiconductor substrate, forming a mask in the passive region and then etching the upper undoped cladding layer in the modulation region, etching the etch stop layer in the modulation region, removing the mask and then forming a p-type cladding layer and a contact layer in that order on the lower undoped cladding layer in the modulation region and on the upper undoped cladding layer in the passive region, removing the contact layer in the passive region, and forming a P-side electrode on the contact layer in the modulation region.

Other and further objects, features and advantages of the invention will appear more fully from the following description.

### BRIEF DESCRIPTION OF THE DRAWINGS

FIG. 1 is a plan view of an optical modulator of the first embodiment;

FIG. 2 is a cross-sectional view taken along dashed line X-X′ of FIG. 1;

FIG. 3 is a flowchart illustrating the method of manufacturing the optical modulator of the first embodiment;

FIG. 4 includes cross-sectional views of the optical modulator at various steps in the manufacture of the modulator;

FIG. 5 shows the simulation results of the optical loss in each passive region of the optical modulator of the first embodiment of the present invention;

FIG. 6 includes cross-sectional views illustrating another method of manufacturing the optical modulator of the first embodiment;

FIG. 7 is a cross-sectional view of an optical modulator of the second embodiment of the present invention;

FIG. 8 is a cross-sectional view of an optical modulator of the third embodiment of the present invention;

FIG. 9 is a flowchart illustrating the method of manufacturing the optical modulator of the third embodiment; and

FIG. 10 includes cross-sectional views of the optical modulator at various steps in the manufacture of the modulator.

### DETAILED DESCRIPTION OF THE PREFERRED EMBODIMENTS

### First Embodiment

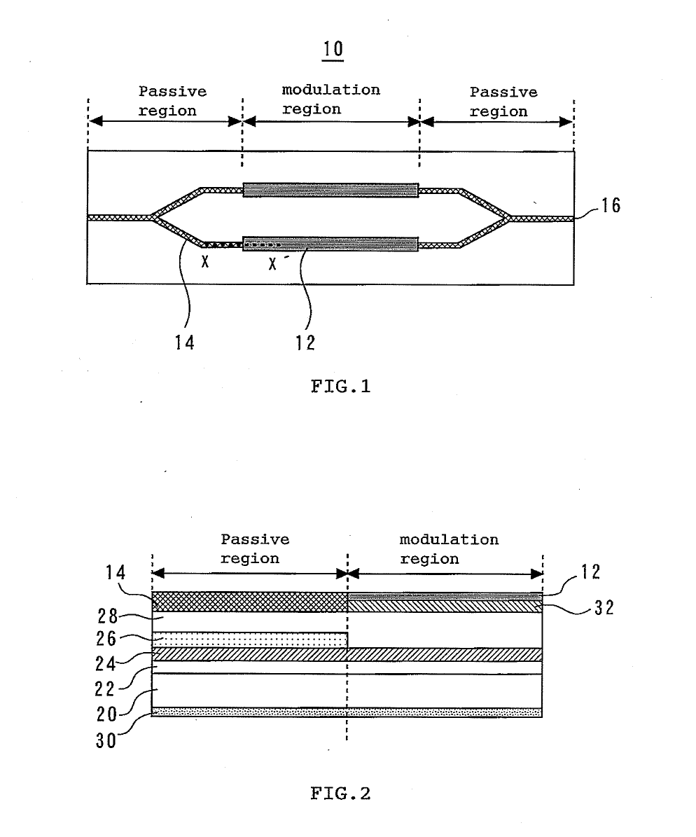

A first embodiment of the present invention will be described with reference to FIGS. 1 to 6. It should be noted that certain of the same or corresponding components are designated by the same reference symbols and described only once.

FIG. 1 is a plan view of an optical modulator 10 of the first embodiment. The optical modulator 10 shown in FIG. 1 is, e.g., a semiconductor Mach-Zehnder modulator in which input light is split into two beams which are then combined together. The optical modulator 10 includes a modulation region for modulating light and passive regions adjacent the modulation region. Two P-side electrodes 12 are formed in the modulation region. Further, a fork-shaped SiO₂ protective film 14 is formed in each passive region. The P-side electrodes 12 are connected to the SiO₂ protective films 14. The P-side electrodes 12 and the SiO₂ protective films 14 are formed on the surface of a high mesa waveguide 16. The modulation region has a longitudinal, or lengthwise, dimension of 1 mm. The passive regions adjacent the modulation region each have a longitudinal dimension of 1 mm. Therefore, the optical modulator 10 has a longitudinal dimension of 3 mm. Further, the high mesa waveguide 16 has a width of 1.8 μm.

FIG. 2 is a cross-sectional view taken along dashed line X-X′ of FIG. 1. As shown in FIG. 2, an n-type cladding layer 22 is formed on a semiconductor substrate 20 in the modulation region and passive regions. The semiconductor substrate 20 is an n-type InP substrate. Further, the n-type cladding layer 22 is an n-type InP layer. The n-type cladding layer 22 has a thickness of, e.g., 200 nm. A core layer 24 is formed on this n-type cladding layer 22. The core layer 24 is made up of i-InGaAsP/InGaAsP multiquantum wells (MQW). Specifically, the core layer 24 has a multiquantum well (MQW) structure including 30 periods of alternating InGaAsP well layers and InGaAsP barrier layers, each having a thickness of 7 nm. The barrier layers have a composition wavelength of 1.1 μm. The composition wavelength of the well layers is selected so that the MQW has a photoluminescence (PL) wavelength of 1.4 μm.

A p-type cladding layer 28 is formed on the core layer 24 in the modulation region and extends into the passive regions. In each passive region, an undoped cladding layer 26 is formed between the core layer 24 and the p-type cladding layer 28, as described later. The p-type cladding layer 28 is a p-type InP layer. The p-type cladding layer 28 has a thickness of, e.g., approximately 1500 nm. Further, the p-type cladding layer 28 has a carrier concentration of, e.g., 1×10¹⁸ cm⁻³. Further, an N-side electrode 30 is formed on the bottom surface of the semiconductor substrate 20. This completes the description of components and layers common to the modulation region and passive regions.

In the modulation region, a contact layer 32 is formed on the p-type cladding layer 28. The contact layer 32 is a p-type InGaAsP layer. The contact layer 32 has a thickness of, e.g., 500 nm. P-side electrodes 12 are formed on the contact layer 32.

In each passive region, the undoped cladding layer 26 is formed between the core layer 24 and the p-type cladding layer 28. The undoped cladding layer 26 is an undoped InP layer. The undoped cladding layer 26 has a thickness of, e.g., 200 nm. Further in each passive region, an SiO₂ protective film 14 is formed on the p-type cladding layer 28. This completes the description of the construction of the optical modulator 10 of the first embodiment.

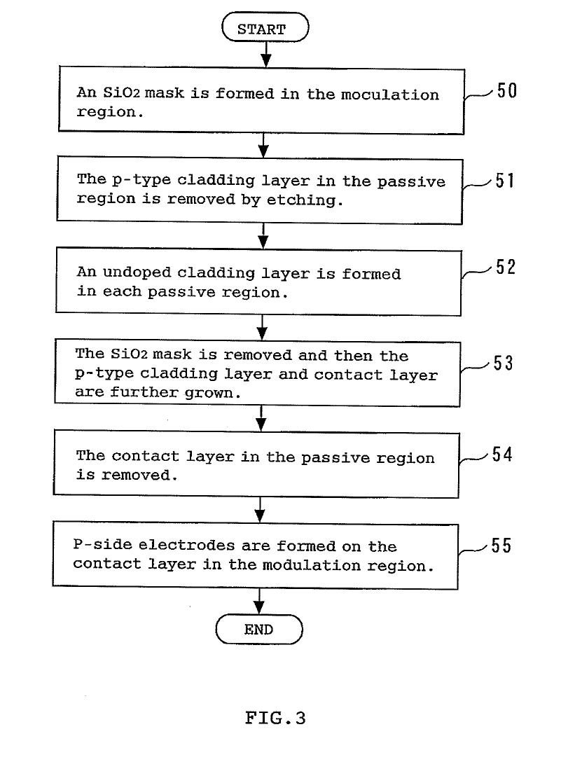

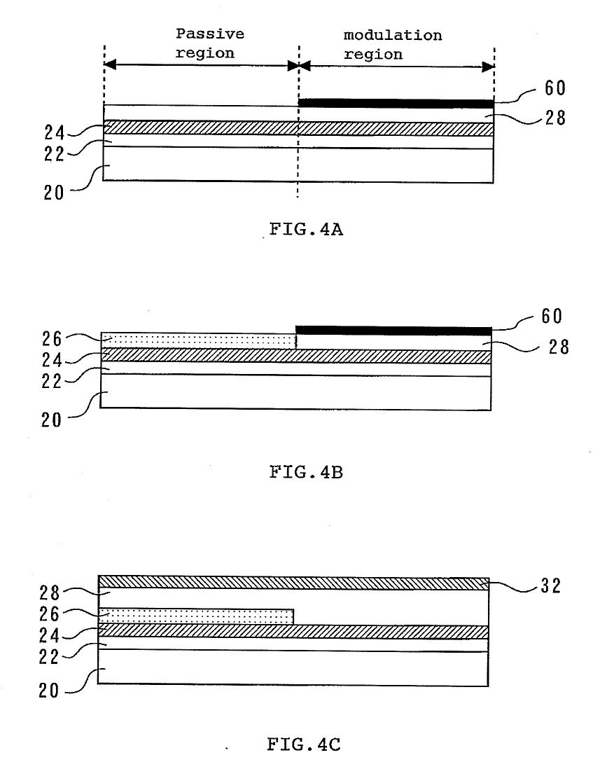

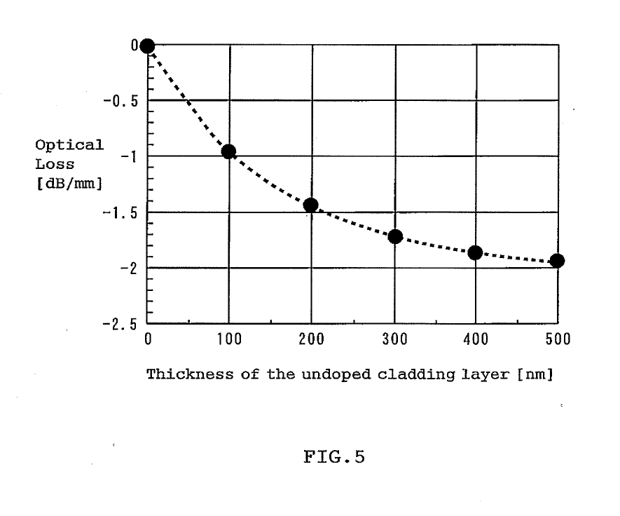

A method of manufacturing the optical modulator 10 will be described with reference to FIGS. 3 and 4. FIG. 3 is a flowchart illustrating the method of manufacturing the optical modulator 10 of the first embodiment. FIG. 4 includes cross-sectional views of the optical modulator 10 at various steps in the manufacture of the modulator. The manufacturing method will now be described with reference to the flowchart of FIG. 3. The method begins by forming an n-type cladding layer 22, a core layer 24, and a p-type cladding layer 28 on a semiconductor substrate 20 by MOCVD. An SiO₂ mask 60 is then formed in the modulation region (step 50). FIG. 4A is a cross-sectional view of the resulting structure after step 50.

After the completion of step 50, the method proceeds to step 51. At step 51, the p-type cladding layer 28 in the passive regions is removed by etching. After the completion of step 51, the method proceeds to step 52. At step 52, an undoped cladding layer 26 is formed in each passive region. This is accomplished by butt joint growth using an MOCVD technique. FIG. 4B is a cross-sectional view of the resulting structure after step 52.

After the completion of step 52, the method proceeds to step 53. At step 53, the SiO₂ mask 60 is removed and then the p-type cladding layer 28 is further grown. A contact layer 32 is then formed on the p-type cladding layer 28. The p-type cladding layer 28 and the contact layer 32 are formed by MOCVD. FIG. 4C is a cross-sectional view of the resulting structure after step 53.

After the completion of step 53, the method proceeds to step 54. At step 54, the contact layer 32 in the passive regions is removed in a mixture of aqueous tartaric acid and hydrogen peroxide solution.

After the completion of step 54, the method proceeds to step 55. At step 55, first a high mesa waveguide 16 is formed by dry etching. Next, an SiO₂ protective film 14 is formed in each passive region. P-side electrodes 12 are then formed on the contact layer 32 in the modulation region. Further, the bottom surface of the semiconductor substrate 20 is polished to reduce its thickness, and an N-side electrode 30 is formed on the polished bottom surface of the semiconductor substrate, thus completing the manufacture of the optical modulator 10 shown in FIGS. 1 and 2.

The optical modulator 10 of the first embodiment is characterized in that the undoped cladding layers 26 are formed in the passive regions but not in the modulation region. In each passive region, the undoped cladding layer 26 acts to reduce the light intensity in the p-type cladding layer 28. That is, the amount of light transmitted from the core layer 24 to the p-type cladding layer 28 is reduced by the undoped cladding layer 26. This results in reduced valence band absorption in the p-type cladding layer 28, resulting in reduced optical loss in the optical modulator 10. On other hand, since the undoped cladding layers 26 are not formed in the modulation region, the modulation region includes only one undoped layer, namely the core layer 24, which corresponds to the i layer in the p-i-n structure of the modulation region. That is, in the p-i-n structure of the modulation region, the thickness of the i layer corresponds to the thickness of the core layer 24, whereas in the p-i-n structure of the passive regions the thickness of the i layer corresponds to the sum of the thicknesses of the core layer 24 and the undoped cladding layer 26. Therefore, although the passive regions include the undoped cladding layers 26 to reduce the optical loss of the optical modulator 10, there is no need to increase the drive voltage of the modulator (since the required drive voltage is determined by the thickness of the i layer in the p-i-n structure of the modulation region). This means that the optical modulator 10 can be driven by a lower voltage than prior art optical modulators of this type.

FIG. 5 shows the simulation results of the optical loss in each passive region of the optical modulator 10 of the first embodiment of the present invention. As shown in FIG. 5, the optical loss decreases with the thickness of the undoped cladding layer 26. Especially, when the thickness of the undoped cladding layer 26 is 100 nm or more, the optical loss in each passive region is at least approximately 1 dB/mm less than when the undoped cladding layer 26 is not present. On the other hand, if the undoped cladding layers 26 are too thick, abnormal crystal growth and inaccurate photolithographic focusing may result. In order to avoid such problems, in accordance with the first embodiment the undoped cladding layers 26 have a thickness of 200 nm. These undoped cladding layers 26 of the first embodiment enable the optical loss to be reduced by 1.44 dB per 1 mm of longitudinal dimension of the passive regions. Since the sum of the longitudinal dimensions of the passive regions of the first embodiment is 2 mm, the construction of the optical modulator 10 enables the optical loss to be reduced by a total of 2.88 dB.

Thus the construction of the optical modulator 10 of the first embodiment allows both the optical loss and the drive voltage of the modulator to be reduced. Furthermore, since the optical modulator 10 has a p-i-n structure, it can be easily monolithically integrated with a semiconductor laser.

Although in the first embodiment the present invention is shown as applied to an optical modulator, it will be understood that the invention may be applied to other apparatus. For example, the present invention may be applied to tunable semiconductor lasers having an active region to which a voltage is applied and passive regions adjacent the active region. Also in these lasers an undoped cladding layer having a thickness of 100 nm or more may be formed between the core layer and the p-type cladding layer in the passive regions to produce the foregoing effect of the present invention.

Further, the present invention may be applied to integrated semiconductor optical devices having an active region to which a voltage is applied and passive regions adjacent the active region. Also in these optical devices an undoped cladding layer having a thickness of 100 nm or more may be formed between the core layer and the p-type cladding layer in the passive regions to produce the foregoing effect of the present invention.

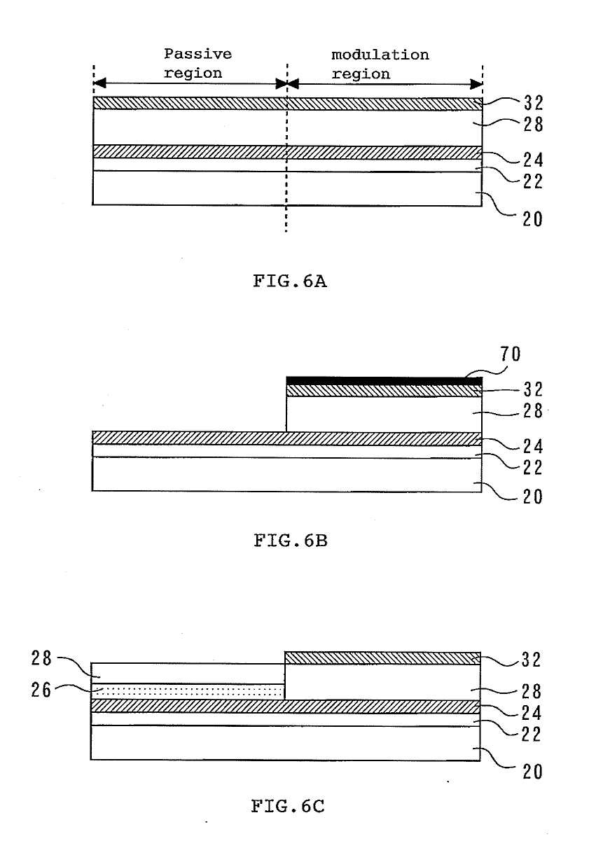

It should be noted that the optical modulator 10 may be manufactured by a method other than that described above. Such a manufacturing method will be described with reference to FIG. 6. FIG. 6 includes cross-sectional views illustrating this method of manufacturing the optical modulator 10 of the first embodiment. The manufacturing method begins by forming an n-type cladding layer 22, a core layer 24, a p-type cladding layer 28, and a contact layer 32 in that order on a semiconductor substrate 20 by MOCVD (FIG. 6A). Next, an SiO₂ mask 70 is formed in the modulation region, and the contact layer 32 and the p-type cladding layer 28 in the passive regions are etched away (FIG. 6B). An undoped cladding layer 26 and an additional p-type cladding layer 28 are then formed in each passive region by butt joint growth using an MOCVD technique. The SiO₂ mask 70 is then removed (FIG. 6C). Next, a high mesa waveguide 16 and P-side electrodes 12 are formed. The semiconductor substrate 20 is then polished to reduce its thickness, and an N-side electrode 30 is formed, thus completing the manufacture of the optical modulator 10. It should be noted that various alterations may be made to the first embodiment without departing from the scope of the present invention.

### Second Embodiment

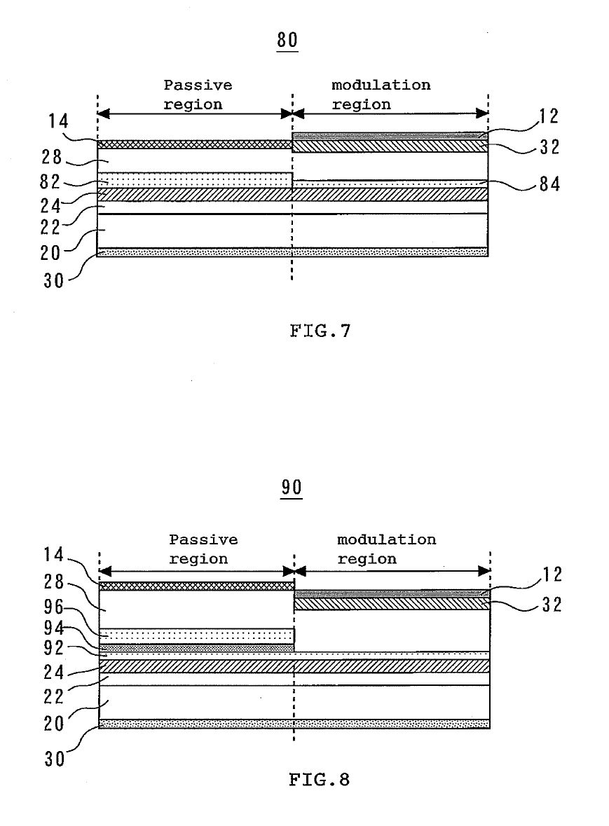

A second embodiment of the present invention will be described with reference to FIG. 7. FIG. 7 is a cross-sectional view of an optical modulator 80 of the second embodiment of the present invention. As shown in FIG. 7, an undoped cladding layer 82 is formed between the core layer 24 and the p-type cladding layer 28 in each passive region of the optical modulator 80. The undoped cladding layer 82 has a thickness of, e.g., 200 nm. Further, a thin undoped cladding layer 84 thinner than the undoped cladding layer 82 is formed between the core layer 24 and the p-type cladding layer 28 in the modulation region. The thin undoped cladding layer 84 has a thickness of, e.g., 10 nm. The undoped cladding layer 82 and the thin undoped cladding layer 84 are InP layers. It should be noted that the plan view of the optical modulator 80 is identical to that shown in FIG. 1.

Generally, the thicker the undoped cladding layers in the modulation region and passive regions of an optical modulator, the lower the optical loss of the modulator. On the other hand, the thinner the undoped cladding layer in the modulation region, the lower the voltage required to drive the optical modulator. However, if no undoped cladding layer is present in the modulation region, it may not be possible to sufficiently reduce the optical loss in the optical modulator solely by increasing the thickness of the undoped cladding layers in the passive regions. In order to avoid this, the modulation region of the optical modulator 80 includes the thin undoped cladding layer 84 thinner than the undoped cladding layers 82 in the passive regions. This construction results in reduced optical loss in the optical modulator. Further, since the thickness of the undoped cladding layer 84 is thin (10 nm), there is only a slight increase in the voltage required to drive the optical modulator.

It should be noted that the thin undoped cladding layer 84 preferably has a thickness of 10 nm or more, since if the thin cladding layer 84 has a thickness less than 10 nm, it cannot sufficiently reduce the optical loss.

### Third Embodiment

A third embodiment of the present invention will be described with reference to FIGS. 8 to 10. FIG. 8 is a cross-sectional view of an optical modulator 90 of the third embodiment of the present invention. As shown in FIG. 8, in each passive region of the optical modulator 90, an upper undoped cladding layer 96 and a lower undoped cladding layer 92 are formed in contact with the p-type cladding layer 28 and the core layer 24, respectively. The upper and lower undoped cladding layers 96 and 92 are undoped InP layers. The upper undoped cladding layer 96 has a thickness of, e.g., 200 nm. The lower undoped cladding layer 92 has a thickness of, e.g., 10 nm. The lower undoped cladding layer 92 extends into between the core layer 24 and the p-type cladding layer 28 in the modulation region. The upper undoped cladding layer 96, however, is not formed in the modulation region.

An etch stop layer 94 (an undoped layer) is formed between the upper and lower undoped cladding layers 96 and 92. The etch stop layer 94 is an undoped InGaAsP layer. The etch stop layer 94 has a thickness of, e.g., 20 nm. Further, the etch stop layer 94 has a composition wavelength of 1.2 μm. The etch stop layer 94 can be selectively etched relative to undoped cladding layers (i.e., the upper and lower undoped cladding layers 96 and 92). This completes the description of the construction of the optical modulator 90 of the third embodiment. It should be noted that the plan view of the optical modulator 90 is identical to that shown in FIG. 1.

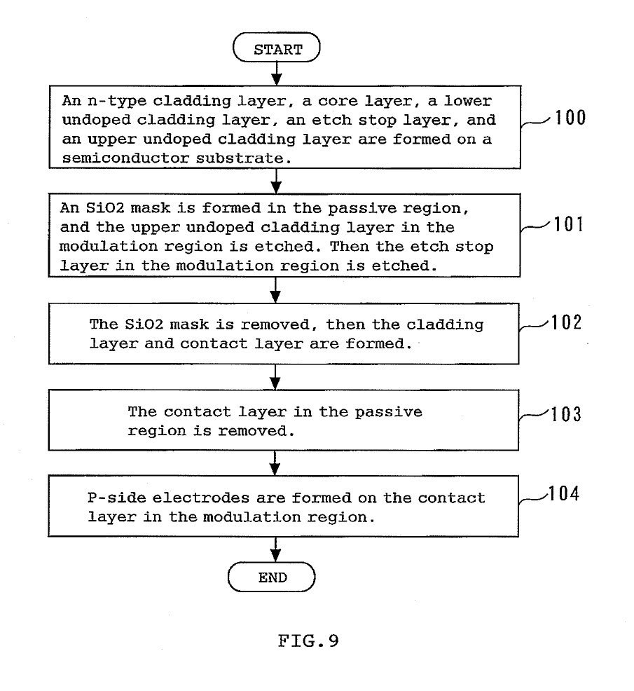

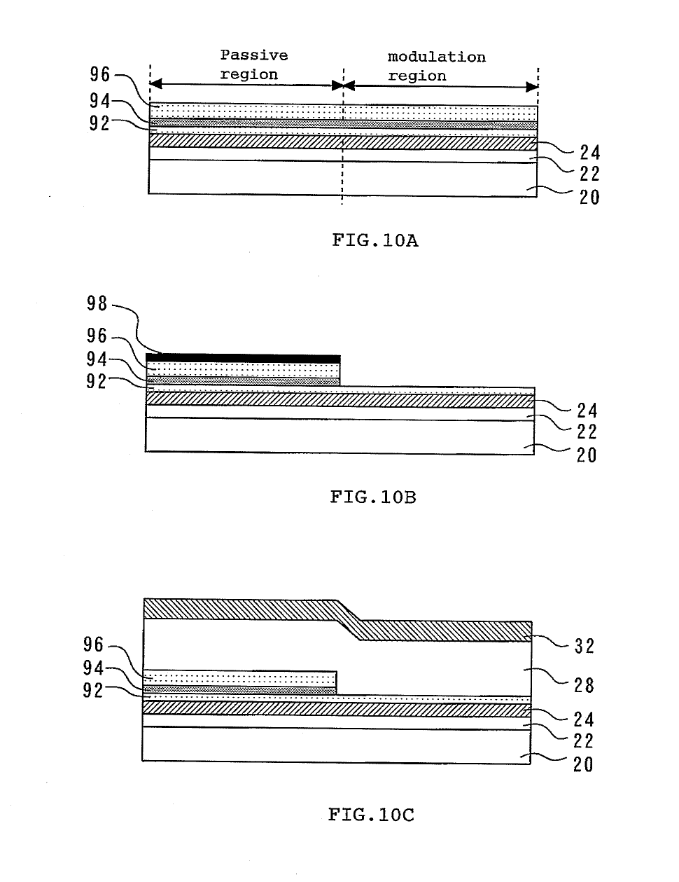

A method of manufacturing the optical modulator 90 will be described with reference to FIGS. 9 and 10. FIG. 9 is a flowchart illustrating the method of manufacturing the optical modulator 90 of the third embodiment. FIG. 10 includes cross-sectional views of the optical modulator 90 at various steps in the manufacture of the modulator. The manufacturing method will now be described with reference to the flowchart of FIG. 9. The method begins by forming an n-type cladding layer 22, a core layer 24, a lower undoped cladding layer 92, an etch stop layer 94, and an upper undoped cladding layer 96 in that order on a semiconductor substrate 20 (step 100). The formation of each layer is accomplished by MOCVD. FIG. 10A is a cross-sectional view of the resulting structure after step 100.

After the completion of step 100, the method proceeds to step 101. At step 101, an SiO₂ mask 98 is formed in the passive regions, and the upper undoped cladding layer 96 in the modulation region is etched in a mixture of aqueous hydrochloric acid and phosphoric acid. This etching can be stopped at the upper surface of the etch stop layer 94, since the etch rate of the etch stop layer 94 in the mixture is very slow. The etch stop layer 94 in the modulation region is then also etched. This etching is performed in a mixture of aqueous tartaric acid and hydrogen peroxide solution. FIG. 10B is a cross-sectional view of the resulting structure after step 101.

After the completion of step 101, the method proceeds to step 102. At step 102, first the SiO₂ mask 98 is removed. A p-type cladding layer 28 and a contact layer 32 are then formed in that order on the lower undoped cladding layer 92 in the modulation region and on the upper undoped cladding layers 96 in the passive regions. The formation of these layers is accomplished by MOCVD. FIG. 10C is a cross-sectional view of the resulting structure after step 102.

After the completion of step 102, the method proceeds to step 103. At step 103, the contact layer 32 in the passive regions is removed in a mixture of aqueous tartaric acid and hydrogen peroxide solution.

After the completion of step 103, the method proceeds to step 104. At step 104, first a high mesa waveguide 16 is formed by dry etching. Next, an SiO₂ protective film 14 is formed in each passive region. P-side electrodes 12 are then formed on the contact layer 32 in the modulation region. Further, the bottom surface of the semiconductor substrate 20 is polished to reduce its thickness, and an N-side electrode 30 is formed on the polished bottom surface of the semiconductor substrate 20, thus completing the manufacture of the optical modulator 90 shown in FIG. 8.

In this method of manufacturing the optical modulator 90 in accordance with the third embodiment, when the upper undoped cladding layer 96 is etched, the etch stop layer 94 covering the lower undoped cladding layer 92 prevents the etching of the lower undoped cladding layer 92. This ensures that the lower undoped cladding layer 92 has the desired thickness.

Thus the present invention provides an improved optical modulator operable with a decreased drive voltage which exhibits a decreased optical loss and which can be easily monolithically integrated with a semiconductor laser.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-073125, filed on Mar. 26, 2010 including specification, claims, drawings and summary, on which the Convention priority of the present application is based, are incorporated herein by reference in its entirety.

1. An optical modulator comprising:
a modulation region for modulating light; and
a passive region adjacent said modulation region, wherein
said modulation region and said passive region include, in common, a semiconductor substrate, an n-type cladding layer on said semiconductor substrate, a core layer on said n-type cladding layer, and a p-type cladding layer on said core layer,
said modulation region further includes a contact layer on said p-type cladding layer, and a P-side electrode on said contact layer, and
said passive region further includes a first undoped cladding layer between said core layer and said p-type cladding layer.

2. The optical modulator according to claim 1, wherein said first undoped cladding layer has a thickness of at least 100 nm.

3. The optical modulator according to claim 1, wherein
said modulation region further includes a second undoped cladding layer between said core layer and said p-type cladding layer, and
said second undoped cladding layer is thinner than said first undoped cladding layer in said passive region.

4. The optical modulator according to claim 3, wherein said second undoped cladding layer has a thickness of at least 10 nm.

5. The optical modulator according to claim 1, wherein
said first undoped cladding layer includes an upper undoped cladding layer in contact with said p-type cladding layer, and a lower undoped cladding layer in contact with said core layer;
said optical modulator includes an undoped layer located between said upper and lower undoped cladding layers; and
said lower undoped cladding layer extends between said core layer and said p-type cladding layer in said modulation region.

6. A method of manufacturing an optical modulator including a modulation region for modulating light and a passive region adjacent said modulation region, the method comprising:
forming an n-type cladding layer, a core layer, a lower undoped cladding layer, an etch stop layer, and an upper undoped cladding layer, in that order, on a semiconductor substrate;
forming an etching mask in said passive region and, thereafter, etching said upper undoped cladding layer in said modulation region;
removing said etch stop layer in said modulation region;
removing said etching mask and, thereafter, forming a p-type cladding layer and a contact layer, in that order, on said lower undoped cladding layer in said modulation region and on said upper undoped cladding layer in said passive region;
removing said contact layer in said passive region; and
forming a P-side electrode on said contact layer in said modulation region.
